(19) United States
(12) Patent Application Publication
(10) Pub. No.: US 2026/0114254 A1
(43) Pub. Date: Apr. 23, 2026

(54) LOW-K DIELECTRIC FILM REPAIR FOR BOTTOM-UP METAL GROWTH

(71) Applicant: Applied Materials, Inc., Santa Clara, CA (US)

(72) Inventors: Xinyi LU, Santa Clara, CA (US); Kent Qiujing ZHAO, San Francisco, CA (US); Bo XIE, San Jose, CA (US); Chi-I LANG, Cupertino, CA (US); Li-Qun XIA, Cupertino, CA (US)

(21) Appl. No.: 19/347,060

(22) Filed: Oct. 1, 2025

Related U.S. Application Data
(60) Provisional application No. 63/709,563, filed on Oct. 21, 2024.

(51) Int. Cl. H01L 21/768; C23C 16/02; C23C 16/04; C23C 16/06; C23C 16/52

(52) U.S. Cl. CPC H10W 20/096; C23C 16/0272; C23C 16/045; C23C 16/06; C23C 16/52; H10W 20/056; H10W 20/095

(57) ABSTRACT

A surface recovery process that restores the hydrophobicity of dielectric surfaces and promotes selective deposition of metal-fill such as molybdenum onto metal-containing surfaces while reducing or preventing growth on the dielectric surfaces. Additionally, the surface recovery process reduces film loss against subsequent wet etching processes such as DHF. The recovery precursor soak is performed with optional UV (concurrent or sequential) to react with silanols on damaged dielectric surface to replenish —CH3 and recover hydrophobicity of the dielectric surface. The recovery precursor is a carbon-containing recovery precursor, for example, organohalosilanes, esters, silyl ethers, organoaminosilanes, silyl esters, hydrocarbons, or a combination thereof.

### CROSS REFERENCE TO RELATED APPLICATIONS

This application claims the benefit of U.S. Provisional Patent Application Ser. No. 63/709,563, filed Oct. 21, 2024, which is incorporated by reference herein in its entirety.

### TECHNICAL FIELD

The present disclosure generally relates to semiconductor device fabrication. More particularly, the present disclosure generally relates to semiconductor devices that include low resistance contacts and a method for manufacturing the same.

### BACKGROUND

Integrated circuits have evolved into complex devices that can include millions of transistors, capacitors, and resistors on a single chip. During integrated circuit evolution, functional density (i.e., the number of interconnected devices per chip area) has generally increased while geometry size (i.e., the smallest component (or line) that can be created using a fabrication process) has decreased.

Microelectronic devices are fabricated on a semiconductor substrate as integrated circuits in which various conductive layers are interconnected with one another to permit electronic signals to propagate within the device. An example of such a device includes memory (e.g., DRAM) and logic devices, including both planar and three-dimensional structures. An example of a three-dimensional structure is a finFET or MOSFET devices.

In a traditional interconnect formation process, a feature, such as a via or trench is fabricated in the semiconductor substrate. The contact allows connections between various semiconductor structures. Contacts with low resistance are desirable in semiconductor devices. However, when a contact has a relatively high resistance, a poor connection is created, which reduces the overall performance of the packaged semiconductor structures.

Therefore, there is a need in the art for a process that provides contacts with low resistance.

### SUMMARY

The present disclosure generally relates to semiconductor device fabrication. More particularly, the present disclosure generally relates to semiconductor devices that include low resistance contacts and a method for manufacturing the same.

In one or more implementations which can be combined with other implementations, a method for processing a semiconductor device structure is provided. The method includes introducing a carbon-containing recovery precursor into a processing region of a processing chamber where the semiconductor device structure is disposed. The semiconductor device structure has a feature, the feature having sidewall surfaces defined by a silicon-containing dielectric material and a bottom surface extending between the sidewall surfaces, the bottom surface defined by a metal-containing material. The method further includes exposing the semiconductor device structure to the carbon-containing recovery precursor to increase the hydrophobicity of the sidewall surfaces defined by the silicon-containing dielectric material.

Implementations may include one or more of the following. The method further includes filling the feature with a metal-fill material, including preferentially growing the metal-fill material from the bottom surface defined by the metal-containing material. The metal-fill material is molybdenum, and the metal-containing material is tungsten. The method further includes exposing the semiconductor device substrate to UV light during at least a portion of a time when the carbon-containing recovery precursor is in the processing region. The method further includes exposing the semiconductor device structure to UV light prior to introducing the carbon-containing recovery precursor into the processing region. The method further includes exposing the semiconductor device structure to UV light after removing the carbon-containing recovery precursor from the processing region. The recovery precursor includes a molecule selected from a group consisting of

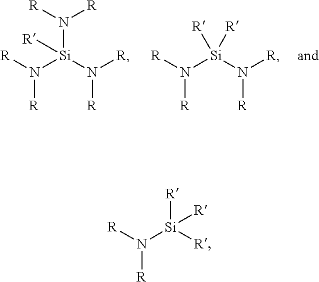

wherein R is independently selected from Me, Et, iPr, tBu, and H, or R and R are joined to form a cyclic chain on one or more N atoms, and R′ is an alkyl, alkenyl, or an alkynyl. The recovery precursor includes a molecule selected from a group consisting of

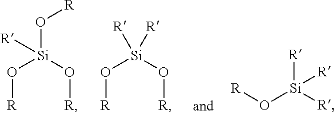

wherein R is independently selected from Me, Et, iPr, and tBu, and R′ is an alkyl, alkenyl, or an alkynyl. The recovery precursor includes a molecule selected from a group consisting of

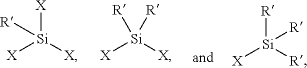

wherein X is Cl, Br, or I, and R′ is an alkyl, alkenyl, or an alkynyl. The recovery precursor includes a molecule with a formula:

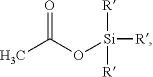

wherein R′ is an alkyl, alkenyl, or an alkynyl. The recovery precursor comprises a molecule with a formula:

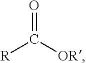

wherein R is hydrogen, an alkyl, an alkenyl, an alkynyl, or an aryl, and R′ is hydrogen, an alkyl, an alkenyl, an alkynyl, or an aryl. The recovery precursor includes a molecule with a formula:

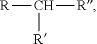

wherein R is hydrogen, an alkyl, an alkenyl, an alkynyl, or an aryl, R′ is hydrogen, an alkyl, an alkenyl, an alkynyl, or an aryl, and R″ is hydrogen, an alkyl, an alkenyl, an alkynyl, or an aryl.

In one or more implementations which can be combined with other implementations, a non-transitory computer-readable medium storing instructions that, when executed by a processor, cause a computer system to perform a plurality of operations. The plurality of operations includes introducing a carbon-containing recovery precursor into a processing region of a processing chamber where the semiconductor device structure is disposed. The semiconductor device structure has a feature formed thereon, the feature having sidewall surfaces defined by a silicon-containing dielectric material and a bottom surface extending between the sidewall surfaces, the bottom surface defined by a metal-containing material. The plurality of operations further includes exposing the semiconductor device structure to the carbon-containing recovery precursor to increase the hydrophobicity of the sidewall surfaces defined by the silicon-containing dielectric material.

Implementations may include one or more of the following. The non-transitory computer-readable medium further includes filling the feature with a metal-fill material, comprising preferentially growing the metal-fill material from the bottom surface defined by the metal-containing material. The non-transitory computer-readable further includes turning on a UV light source to expose the semiconductor device structure to UV light. The non-transitory computer-readable further includes adjusting a flow rate of the carbon-containing recovery precursor to be in a range from about 100 mgm to about 2000 mgm. The non-transitory computer-readable medium further includes adjusting a pressure inside the process chamber to be in a range from about 3 Torr and about 100 Torr and adjusting a temperature inside the process chamber to be in a range from about 75° C. to about 500° C.

In one or more implementations, which can be combined with other implementations, a process chamber is provided. The process chamber includes a chamber body; a UV transparent gas distribution showerhead, the chamber body and the UV transparent gas distribution showerhead defining a processing volume; a UV light source positioned to delivery UV radiation into the processing volume; a process gas source adapted to deliver a processing gas comprising a carbon-containing recovery precursor to the inner volume; and a system controller. The system controller includes a memory that stores computer readable instructions and a processor coupled to the memory. The processor is configured by the computer readable instructions that when executed by the processor perform a plurality of operations for processing a semiconductor device structure. The plurality of operations includes introducing the carbon-containing recovery precursor into the processing volume where the semiconductor device structure is disposed. The semiconductor device structure has a feature, the feature having sidewall surfaces defined by a silicon-containing dielectric material and a bottom surface extending between the sidewall surfaces, the bottom surface defined by a metal-containing material. The plurality of operations further includes exposing the semiconductor device structure to the carbon-containing recovery precursor to increase the hydrophobicity of the sidewall surfaces defined by the silicon-containing dielectric material.

Implementations may include one or more of the following. The plurality of operations further includes turning on the UV light source to expose the semiconductor device structure to UV light. The plurality of operations further include adjusting a flow rate of the carbon-containing recovery precursor to be in a range from about 100 mgm to about 2000 mgm; adjusting a pressure inside the process chamber to be in a range from about 3 Torr and about 100 Torr; and adjusting a temperature inside the process chamber to be in a range from about 75° C. to about 500° C.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional view of a process chamber in accordance with one or more implementations of the present disclosure.

FIG. 2 is a flow diagram depicting a method of forming an electrical connection of a semiconductor structure in accordance with one or more embodiments of the present disclosure.

FIGS. 3A-3D illustrate views of various stages of forming an electrical connection of a semiconductor structure in accordance with one or more embodiments described herein.

FIGS. 4A-4C illustrate molecular views of a low-k film during a method, according to one or more embodiments described herein.

FIG. 5 illustrates a schematic top view of a multi-chamber processing system, according to one or more embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure generally relates to semiconductor device fabrication. More particularly, the present disclosure generally relates to semiconductor devices that include low resistance contacts and a method for manufacturing the same.

In a traditional middle-of-the-line (MOL) interconnect formation process, a feature, such as a via or trench, is fabricated in the semiconductor substrate. MOL contact allows connections between front-end-of-the-line (FEOL) semiconductor structures and back-end-of-the-line (BEOL) interconnects. Contacts with low resistance are desirable in semiconductor devices. However, when a MOL interconnect has a relatively high resistance, a poor connection is created at the MOL interconnect, which reduces the overall performance of the packaged semiconductor structures.

Etching, ashing, and wet-cleaning damage dielectric films in MOL leading to increased hydrophilicity of the dielectric films. As a result of the increased hydrophilicity, metal deposition demonstrates less selectivity between the dielectric sidewalls and the metal gate. Currently, if the metal fill material grows on the dielectric sidewalls, voids are introduced in the metal fill and the metal fill is incomplete, which can increase the resistance of the final structure. An additional cleaning process is required for cleaning and removing the metal fill from the sidewalls, which increases the complexity of the interconnect formation process. In addition, the damaged dielectric film is also more vulnerable against subsequent wet etch processes.

Some embodiments of the present disclosure provide a surface recovery process that restores the hydrophobicity of dielectric surfaces and promotes selective deposition of metal-fill such as molybdenum onto metal-containing surfaces while reducing or preventing growth on the dielectric surfaces. Additionally, the surface recovery process reduces film loss against subsequent wet etching processes such as DHF. Restoration of hydrophobicity of dielectric sidewalls through the method described herein, inhibits metal growth along the dielectric sidewalls. As a result, metal-fill deposits mainly on the bottom metal gate and not on the sidewalls. This eliminates the need for the conventional wet clean process performed during current metal-fill processes.

In one or more embodiments, a recovery precursor soak is performed with optional UV (concurrent or sequential) to react with silanols on damaged dielectric surface to replenish —CH3 and recover hydrophobicity of the dielectric surface. The recovery precursor is a carbon-containing recovery precursor. The recovery precursor can be an organosilicon compound. The recovery precursor can be selected from organohalosilanes, esters, silyl ethers, organoaminosilanes, silyl esters, hydrocarbons, or a combination thereof.

In one or more embodiments, the recovery precursor is or includes an organoaminosilane. The organoaminosilane can have the formula R′p-Si—(N—R2)(4-p), where R is independently selected from Me, Et, iPr, tBu, or R and R are joined to form a cyclic chain on one or more N atoms. R′ is an organyl; and p is 1 to 3. The organyl can be independently selected from an alkyl, alkenyl, and alkynyl. The alkyl, alkenyl, and alkynyl can be C1 to C20.

In one or more embodiments, the recovery precursor is or includes a silyl ether. The silyl ether can have the formula R′m-Si—(O—R)(4-m), where R is independently selected from Me, Et, iPr, tBu; R′ is an organyl; and m is 1 to 3. The organyl can be independently selected from an alkyl, alkenyl, and alkynyl. The alkyl, alkenyl, and alkynyl can be C1 to C20.

In one or more embodiments, the recovery precursor is or includes an organohalosilane. The organohalosilane can have the formula Rn—Si—X(4-n), where R is an organic functional group independently selected from a C1 to C20 alkyl, alkenyl, and alkynyl; X is Cl, Br, or I; and n is 1 to 3. The recovery precursor can be an organochlorosilane having the formula Rn—Si—Cl(4-n), where R is an organic functional group such as a C1 to C20 alkyl, alkenyl, and alkynyl; and n is 1 to 3.

In one or more embodiments, the recovery precursor is or includes a silyl ester. The silyl ester can have the formula R—C(═O)—O—SiR′3 where R′ is independently selected from an alkyl, alkenyl, and alkynyl. The alkyl, alkenyl, and alkynl can be C1 to C20.

In one or more embodiments, the recovery precursor is or includes an ester. The ester can have the formula (R—C(═O)—O—R′) where R is independently selected from hydrogen and an organyl and R′ is an organyl. The organyl can be selected from an alkyl, alkenyl, alkynyl, and aryl. The alkyl, alkenyl, alkynyl, and aryl can be C1 to C20.

In one or more embodiments, the recovery precursor is or includes a hydrocarbon. The hydrocarbon can have the formula R—CH—R′—R″ where R, R′, and R″ are independently selected from hydrogen, alkyl, alkenyl, alkynyl, and aryl groups.

The restored surface will not allow metal film to grow on top, as a result, the metal fill material such as molybdenum mainly grows on the bottom metal gate and eliminates the need for an additional sidewall cleaning process. Additionally, the restored hydrophobicity on the dielectric surface also repels aqueous solutions, providing protection against subsequent wet etch processes, such as DHF.

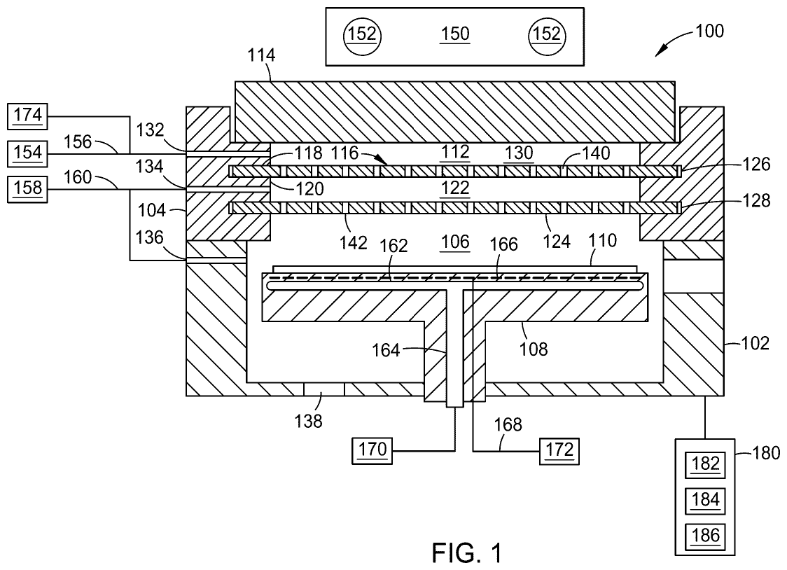

FIG. 1 is a schematic cross-sectional view of a processing chamber 100, according to one or more embodiments. The processing chamber 100 may be a vapor deposition chamber that includes UV radiation for assisting a silylation reaction. In one or more embodiments, the processing chamber 100 may be the ONYX® or the SILENA® process chamber available from Applied Materials, Inc., of Santa Clara, California. The processing chamber 100 may include a chamber body 102 and a chamber lid 104 disposed over the chamber body 102. The chamber body 102 and the chamber lid 104 may form a processing volume 106. A substrate support assembly 108 may be disposed in the processing volume 106. The substrate support assembly 108 may receive and support a substrate 110 thereon for processing.

A first UV transparent gas distribution showerhead 116 may be hung in the processing volume 106 through a central opening 112 of the chamber lid 104 by an upper clamping member 118 and a lower clamping member 120. The first UV transparent gas distribution showerhead 116 may be positioned facing the substrate support assembly 108 to distribute one or more processing gases across a distribution volume 122 which is below the first UV transparent gas distribution showerhead 116. A second UV transparent gas distribution showerhead 124 may be hung in the processing volume 106 through the central opening 112 of the chamber lid 104 below the first UV transparent gas distribution showerhead 116. Each of the UV transparent gas distribution showerheads 116, 124 may be disposed in a recess formed in the chamber lid 104. A first recess 126 may be an annular recess around an internal surface of the chamber lid 104, and the first UV transparent gas distribution showerhead 116 fits into the first recess 126. Likewise, a second recess 128 may receive the second UV transparent gas distribution showerhead 124.

A UV transparent window 114 may be disposed above the first UV transparent gas distribution showerhead 116. The UV transparent window 114 may be positioned above the first UV transparent gas distribution showerhead 116 forming a gas volume 130 between the UV transparent window 114 and the first UV transparent gas distribution showerhead 116. The UV transparent window 114 may be secured to the chamber lid 104 by any means, such as clamps, screws, bolts, etc.

The UV transparent window 114 and the first and second UV transparent gas distribution showerheads 116, 124 may be at least partially transparent to thermal or radiant energy within the UV wavelengths. The UV transparent window 114 may be quartz or another UV transparent material, such as sapphire, CaF₂, MgF₂, AlON, a silicon oxide material, a silicon oxynitride material, or another transparent material.

A UV source 150 may be disposed above the UV transparent window 114. The UV source 150 may be configured to generate UV energy and project the UV energy towards the substrate support assembly 108 through the UV transparent window 114, the first UV transparent gas distribution showerhead 116, and the second UV transparent gas distribution showerhead 124, thus exposing the substrate 110 on the substrate support assembly 108 to UV light. A cover (not shown) may be disposed above the UV source 150. In one or more embodiments, the cover may be shaped to assist the projection of the UV energy from the UV source 150 towards the substrate support.

In one or more embodiments, the UV source 150 may include one or more UV lights 152 to generate UV radiation. The UV lights 152 may be lamps, LED emitters, or other UV emitters. In one or more embodiments, the UV lights 152 may be argon lamps discharging radiation at 126 nm, krypton lamps discharging at 146 nm, xenon lamps discharging at 172 nm, krypton chloride lamps discharging at 222 nm, xenon chloride lamps discharging at 308 nm, mercury lamps discharging at 254 nm or 365 nm, metal vapor lamps such as zinc discharging at 214 nm, rare earth near-UV lamps such as europium-doped strontium borate or fluoroborate lamps discharging at 368-371 nm, to name a few examples.

The processing chamber 100 may include flow channels 132, 134, 136 configured to supply one or more processing gases across the substrate support assembly 108 to process a substrate 110 disposed thereon. A first flow channel 132 provides a flow pathway for gas to enter the gas volume 130 and to be exposed to UV radiation from the UV source 150. The gas from the gas volume 130 may flow through the first UV transparent gas distribution showerhead 116 into the distribution volume 122. A second flow channel 134 may provide a flow pathway for precursor compounds and gases to enter the distribution volume 122 directly without passing through the first UV transparent gas distribution showerhead 116 to mix with the gas that was previously exposed to UV radiation in the gas volume 130. The mixed gases in the distribution volume 122 may be further exposed to UV radiation through the first UV transparent gas distribution showerhead 116 before flowing through the second UV transparent gas distribution showerhead 124 into a space proximate the substrate support assembly 108. The gas proximate the substrate support assembly 108, and a substrate disposed on the substrate support assembly 108, is further exposed to the UV radiation through the second UV transparent gas distribution showerhead 124. Purge gases may be provided through an opening 138 in the bottom of the processing chamber 100 such that the purge gas flow around the substrate support assembly 108, preventing intrusion of processing gases into the space under the substrate support assembly 108. One or more gases may be exhausted through the opening 138.

The first UV transparent gas distribution showerhead 116 may include a plurality of holes 140 that allow processing gas to flow from the gas volume 130 to the distribution volume 122. The second UV transparent gas distribution showerhead 124 may also include a plurality of holes 142 that allow processing gas to flow from the distribution volume 122 into the processing space proximate the substrate support assembly 108. The holes 140, 142 in the first and second UV transparent gas distribution showerheads 116, 124 may be evenly distributed or irregularly spaced.

A carrier gas or purge gas source 154 may be coupled to the first flow channel 132 through a conduit 156. Purge gas from the purge gas source 154 may be provided through the first flow channel 132 during substrate processing to prevent intrusion of process gases into the gas volume 130. A cleaning gas source 174 may also be coupled to the first flow channel 132 through the conduit 156 to provide cleaning of the conduit 156, the first flow channel 132, the gas volume 130, and the rest of the chamber body 102 when not processing substrates.

A process gas or precursor compound source 158 may be coupled to the second flow channel 134 through a conduit 160 to provide a mixture, as described above, to the chamber body 102. The process gas source 158 may also be coupled to a third flow channel 136. The process gas source 158 is adapted to deliver a processing gas including a recovery precursor and optionally a carrier gas. Appropriate valves may allow selection of one or both of the flow channels 134, 136 for flowing the process gas mixture into the chamber body 102.

Substrate temperature may be controlled by providing heating and cooling features in the substrate support assembly 108. A coolant conduit 164 may be coupled to a coolant source 170 to provide a coolant to a cooling plenum 162 disposed in the substrate support assembly 108. One example of a coolant that may be used is a mixture of 50% ethylene glycol in water, by volume. The coolant flow is controlled to maintain temperature of the substrate at or below a targeted level to promote deposition of UV-activated oligomers or fragments on the substrate. A heating element 166 may also be provided in the substrate support assembly 108. The heating element 166 may be a resistive heater, and may be coupled to a heating source 172, such as a power supply, by a conduit 168. The heating element 166 may be used to heat the substrate during the hardening process described above.

The processing chamber 100 further includes a system controller 180 for controlling processes performed by the processing chamber 100. The system controller 180 can be any type of controller used in an industrial setting, such as a programmable logic controller (PLC). The system controller 180 includes a processor 182, a memory 184, and input/output (I/O) circuits 186. The system controller 180 can further include one or more of the following components (not shown), such as one or more power supplies, clocks, communication components (e.g., network interface card), and user interfaces typically found in controllers for semiconductor equipment.

The memory 184 can include non-transitory memory. The non-transitory memory can be used to store the computer readable instructions, programs and settings described below. The memory 184 can include one or more readily available types of memory, such as read only memory (ROM) (e.g., electrically erasable programmable read-only memory (EEPROM), flash memory, floppy disk, hard disk, or random-access memory (RAM) (e.g., non-volatile random-access memory (NVRAM).

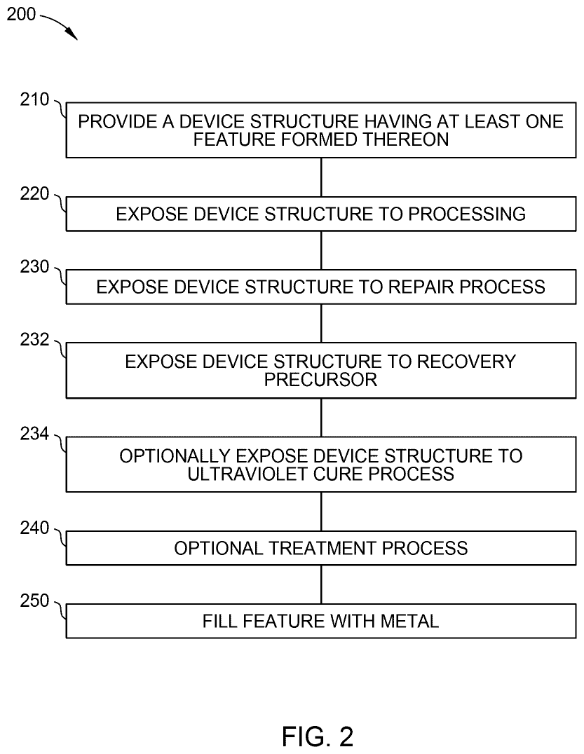

The processor 182 is coupled with the memory. The processor 182 is configured by the computer readable instructions or programs stored in the memory 184 that when executed by the processor 182 perform a plurality of operations, for example, the plurality of operations of the method 200 described in reference to FIG. 2. During execution of these instructions or programs, the system controller 180 can communicate to I/O devices through the I/O circuits 186. For example, during execution of these programs and communication through the I/O circuits 186, the system controller 180 can control outputs (e.g., the UV source 150, the UV lights 152, gas delivery from the gas sources). The memory 184 can further include various operational settings used to control the processing chamber 100. For example, the settings can include temperature and pressure settings as well as settings to control gas delivery from the gas sources described herein.

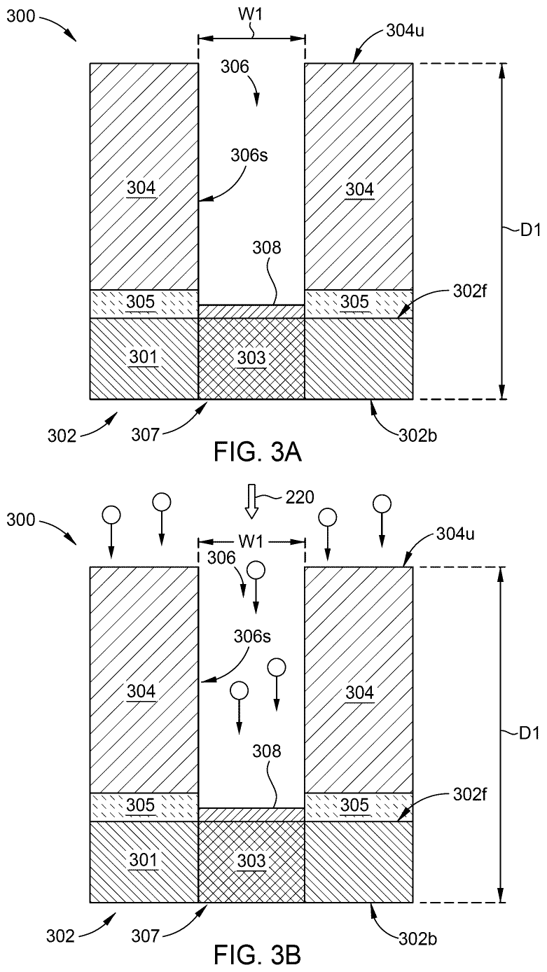

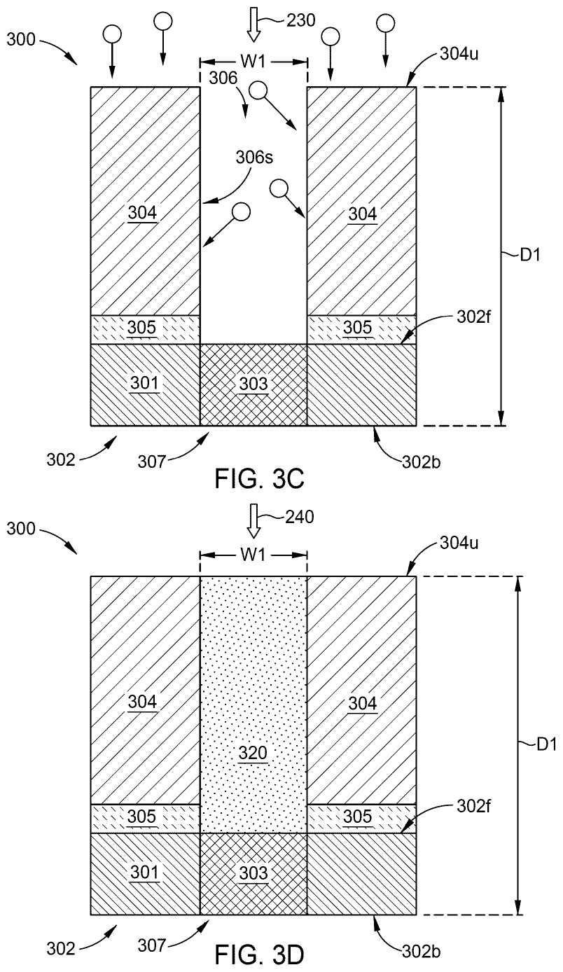

FIG. 2 is a flow diagram depicting a method 200 of forming an electrical connection of a semiconductor device structure, according to one or more of the embodiments described herein. FIGS. 3A-3D illustrate views of various stages of forming an electrical connection of a semiconductor structure in accordance with one or more embodiments described herein. Although FIGS. 3A-3D are described in relation to the method 200, the structures disclosed in FIGS. 3A-3D are not limited to the method 200 but instead may stand alone as structures that are independent of the method 200. Similarly, although the method 200 is described in relation to FIGS. 3A-3D, the method 200 is not limited to the structures disclosed in FIGS. 3A-3D but instead may stand alone independent of the structures disclosed in FIGS. 3A-3D. It should be understood that FIGS. 3A-3D illustrate only partial schematic views of a semiconductor device structure 300, and the semiconductor device structure 300 may contain any number of transistor sections and additional materials having aspects as illustrated in the figures. It should also be noted that although the method 200 illustrated in FIG. 2 is described sequentially, other process sequences that include one or more operations that have been omitted and/or added, and/or has been rearranged in another desirable order, fall within the scope of the embodiments of the disclosure provided herein.

The term “substrate” as used herein refers to a layer of material that serves as a basis for subsequent processing operations. The substrate may be a silicon-based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

Referring to FIG. 2, at operation 210, the semiconductor device structure 300 having a feature formed therein is provided. FIG. 3A illustrates a cross-sectional view of the semiconductor device structure 300 during intermediate stages of manufacturing corresponding to the operation 210. The semiconductor device structure 300 includes a device substrate 302 having one or more layers formed thereon, for example, the dielectric layers 301 and 304, the underlying metal layer 303, and the etch stop layer 305 as is shown in FIG. 3A. The device substrate 302 may be or include a bulk semiconductor substrate, a semiconductor-on-insulator (SOI) substrate, or the like, which may be doped (e.g., with a p-type dopant or an n-type dopant) or undoped. The actual base substrate on which the one or more layers, such as the dielectric layers 301 and 304, underlying the metal layer 303, and the etch stop layer 305, are formed is not shown in FIGS. 3A-3D for simplicity of illustration and discussion. In some embodiments, the semiconductor material of the base substrate portion of the device substrate 302 may include an elemental semiconductor, for example, such as silicon (Si) or germanium (Ge); a compound semiconductor including, for example, silicon carbide, gallium arsenide, gallium phosphide, indium phosphide, indium arsenide, and/or indium antimonide; an alloy semiconductor including, for example, SiGe, GaAsP, AlInAs, GaInAs, GaInP, and/or GaInAsP; a combination thereof, or the like. The device substrate 302 may include additional materials, for example, silicide layers, metal silicide layers, metal layers, dielectric layers, etch stop layers, interlayer dielectrics, or a combination thereof.

The device substrate 302 may further include integrated circuit devices (not shown) that are formed in one or more layers below the layers shown in FIGS. 3A-3D. As one of ordinary skill in the art will recognize, a wide variety of integrated circuit devices such as transistors, diodes, capacitors, resistors, the like, or combinations thereof may be formed in and/or on the device substrate 302 to generate the structural and functional requirements of the design for the resulting semiconductor device structure 300.

The device substrate 302 has a frontside 302f (also referred to as a front surface) and a backside 302b (also referred to as a back surface) opposite the frontside 302f. The dielectric layers 301 and 304, and the etch stop layer 305 are formed over the frontside 302f of the device substrate 302. In one or more embodiments, the etch stop layer 305 is formed between dielectric layer 301 and dielectric layer 304. The dielectric layer 301 is formed over the device substrate 302 (and the additional layers formed over the device substrate 302 (if any)), the etch stop layer 305 is formed over the dielectric layer 301, and the dielectric layer 304 is formed over the etch stop layer 305. The etch stop layer 305 is sandwiched between the dielectric layers 301 and 304.

The dielectric layers 301 and 304 may include multiple layers. The dielectric layer 304 includes an upper surface 304u or field region. In some embodiments, the dielectric layers 301 and 304 includes a dielectric material, such as a low k dielectric. The dielectric material can be selected from silicon oxycarbide (SiOC), silicon oxide, silicon dioxide (SiO₂), silicon nitride (Si₃N₄), silicon carbide (SiC), silicon oxynitride (SiON), aluminum oxide (Al₂O₃), aluminum nitride (AlN), a combination thereof, or multi-layers thereof. In some embodiments, at least one of the dielectric layers 301 and 304 consists essentially of silicon oxide. It is noted that the foregoing descriptors, for example, silicon oxide, should not be interpreted to disclose any particular stoichiometric ratio. Accordingly, “silicon oxide” and the like will be understood by one skilled in the art as a material consisting essentially of silicon and oxygen without disclosing any specific stoichiometric ratio. In one or more embodiments, the etch stop layer 305 includes any suitable material, including but not limited, silicon nitride, silicon carbide, metal oxide, or carbon containing, or combinations thereof.

The semiconductor device structure 300 is patterned to form one or more feature(s) 306. The feature 306 may be a high aspect ratio (HAR) feature. In some embodiments, the feature 306 can be selected from, but not limited to, a trench, a via, a hole, a cavity, or a combination thereof. In particular embodiments, the feature 306 is a trench. In other particular embodiments, the feature 306 is a via. In some embodiments, the feature 306 extends from the upper surface 304u of the dielectric layer 304 towards the backside 302b of the device substrate 302. The feature 306 includes sidewall surface(s) 306s that extend from the field region or the upper surface 304u to the backside 302b.

In some embodiments, an electrical connection, such as electrical connection 307 is formed within the dielectric layer 301 formed at the bottom of the feature 306. The electrical connection 307 may be an interconnect structure, a contact structure, or the like that includes the conductive material found in the underlying metal layer 303. The electrical connection 307 is formed in a prior patterning sequence performed prior to forming the dielectric layer 304 and forming feature 306 therein. For example, as shown in FIG. 3A, the electrical connection 307 may be a contact structure that includes a conductive material. The conductive material may be formed of copper (Cu), cobalt (Co), molybdenum (Mo), tungsten (W), tantalum (Ta), titanium (Ti), or ruthenium (Ru), combinations thereof, and/or nitrides thereof. The feature 306 has a first depth “D1” from the upper surface 304u to the backside 302b and a width “W1” between the two sidewall surface(s) 306s. In some embodiments, the depth D1 is in a range of 2 nm to 200 nm. In some embodiments, the width W1 is in a range of 10 nm to 100 nm. In some embodiments, the feature 306 has an aspect ratio (D/W) in a range of 1 to 20.

At operation 220, the device structure 300 is exposed to a processing operation. In some embodiments, the processing operation of the operation 220 may include etching, ashing, wet cleaning operation, or combinations thereof. In some embodiments, the dielectric layer 304 may be damaged by the processing operations of the operation 220. The processing operations of the operation 220 may decrease the overall number of Si—CH₃ bonds in the dielectric layer 304 and increase the overall number of Si—OH bonds formed in the dielectric layer 304. With the increase of Si—OH bonds, the dielectric layer 304 becomes more hydrophilic, which is undesirable. The increase in hydrophilicity enables the growth of the subsequent metal fill along the sidewall surfaces 306s. In addition, the decrease in Si—CH₃ bonds in the dielectric layer 304 results in an increased k-value of the dielectric layer 304. Further, the processing operations of the operation 220 may include removal of a metal oxide layer 308 on the metal layer 303.

In some embodiments, as shown in FIG. 3A, the semiconductor device structure 300 may have a metal oxide layer 308 or other contaminants formed on the metal layer 303, the sidewall surface(s) 306s, or both the sidewall surface(s) 306s and the metal layer 303. The semiconductor device structure 300 may be exposed to atmosphere prior to or during processing, which may lead to the formation of the metal oxide layer 308 on the surfaces of the metal layer 303. For example, if a vacuum break occurs prior to or during the method 200, the vacuum break can lead to the formation of native oxides. In addition, other processes performed prior to or during the method 200 may lead to the formation of additional contaminants or debris on the sidewall surface(s) 306s and the metal layer 303. In other embodiments, the metal oxide layer 308 may not be present on the surfaces of the metal layer 303.

At operation 220, if present, the metal oxide layer 308 on the metal layer 303 is removed from the metal layer. The operation 220 may be performed in the processing chamber 100 utilizing a reducing agent and optionally UV light. In some embodiments, the device structure 300 may be exposed to UV light during the operation 220. In some embodiments, the reducing agent may be a reducing gas such as ammonia (NH₃), hydrogen (H₂), carbon monoxide (CO), ethanol (C₂H₅OH), methane (CH₄), or ethene (C₂H₄).

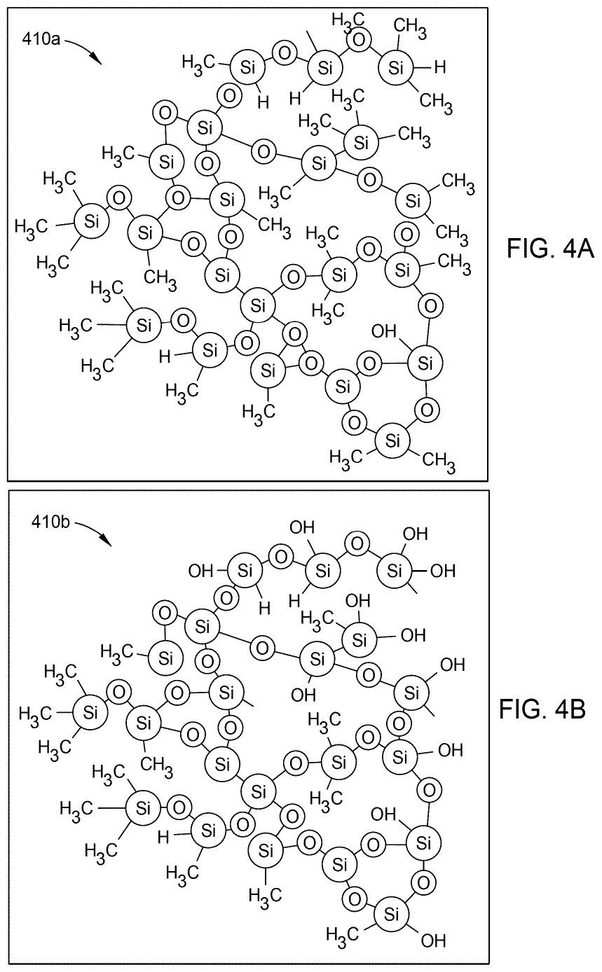

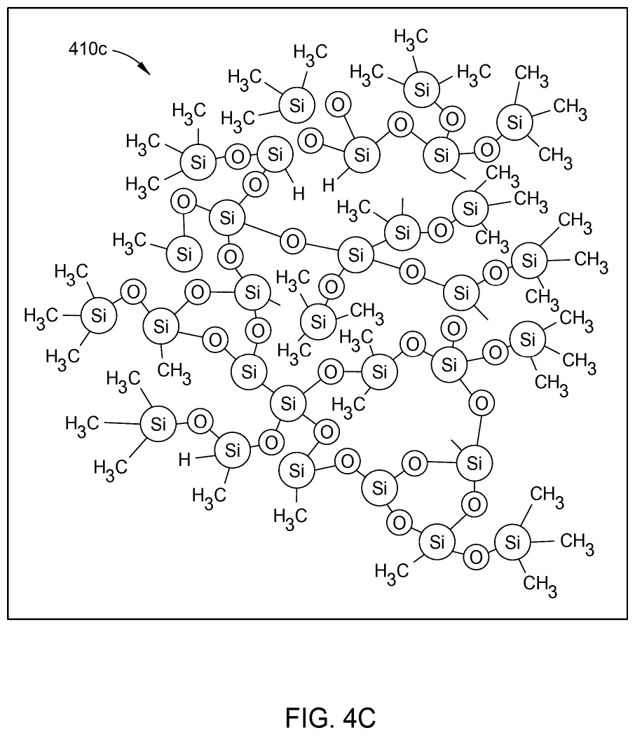

At operation 230, as shown in FIG. 4C, the dielectric layer 304 is repaired. The repair process of operation 230 includes exposing the device structure 300 to a recovery precursor at operation 232 and optionally exposing the device structure to an ultraviolet cure process at operation 234. The repair process of operation 230 may be performed in a processing chamber, for example, the processing chamber 100.

After the process of operation 230, referring to FIG. 4C, the dielectric layer 304, for example, the dielectric film 410c has fewer to no Si—OH bonds and a greater percentage of Si—CH₃ bonds than the dielectric films 410a, 410b shown in FIG. 4A and FIG. 4B, respectively.

In some embodiments, operation 230 may be performed by exposing the device structure 300 to a recovery precursor. In some embodiments, operation 230 may also be performed utilizing UV light, for example, the device structure 300 may be exposed to UV light during operation 232. In some embodiments, operation 230 may be performed via the chemical reactions (1) and (2) shown below. Chemical reactions (1) and (2) illustrate the removal of the Si—OH bonds and the formation of the Si—CH₃ bonds when the dielectric layer 304 is exposed to the recovery precursor

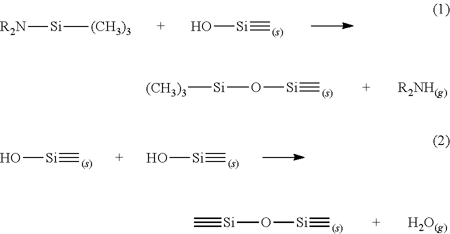

The recovery precursor is a carbon-containing recovery precursor. The recovery precursor can be an organosilicon compound. The recovery precursor can be selected from organohalosilanes, esters, silyl ethers, organoaminosilanes, silyl esters, hydrocarbons, or a combination thereof.

The recovery precursor may include a molecule selected from Group 1. In Group 1, R may be independently selected from Me, Et, iPr, tBu, and H. R′ may be independently selected from an alkyl, an alkenyl, and an alkynyl. R′ may include between one and twenty carbon atoms. R and R may be joined to form a cyclic chain on one or more N atoms. For example, NRR may be joined to form pyridine, pyrrole, or pyrrolidine

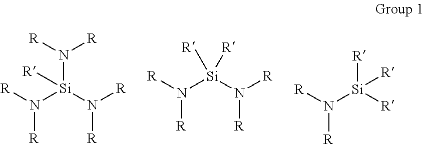

In one or more embodiments, the recovery precursor may be one of the molecules pictured in Group 1 Examples below.

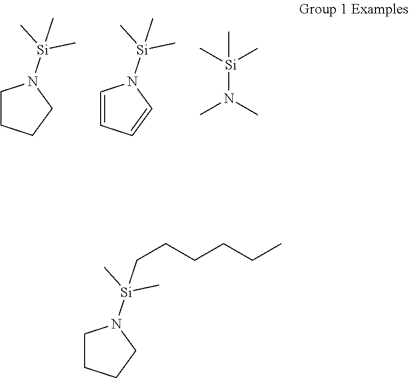

In certain embodiments, the recovery precursor may include a molecule selected from Group 2. In Group 2, R may be independently selected from Me, Et, iPr, and tBu. R′ may be independently selected from an alkyl, an alkenyl, and an alkynyl. R′ may include between one and twenty carbon atoms.

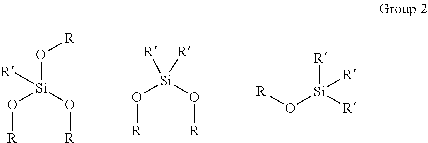

In certain embodiments, the recovery precursor may include a molecule selected from Group 3. In Group 3, X may be Cl, Br, or I. R′ may be independently selected from an alkyl, an alkenyl, and an alkynyl. R′ may include between one and twenty carbon atoms.

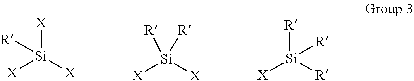

In certain embodiments, the recovery precursor may include a molecule selected from Group 4. In Group 4, R′ may be independently selected from an alkyl, an alkenyl, and an alkynyl. R′ may include between one and twenty carbon atoms.

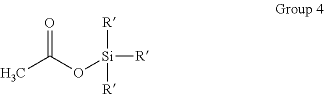

In certain embodiments, the recovery precursor may include a molecule selected from Group 5. In Group 5, R and R′ may be independently selected from hydrogen, an alkyl, an alkenyl, an alkynyl, and an aryl. In embodiments where R and/or R′ contain carbon, R and R′ may include between one and twenty carbon atoms each.

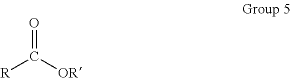

In certain embodiments, the recovery precursor may include a molecule selected from Group 6. In Group 6, R, R′, and R″ may be independently selected from hydrogen, an alkyl, an alkenyl, an alkynyl, and an aryl. In embodiments where R, R,′ and/or R″ contain carbon, R, R′, and R″ may include between one and twenty carbon atoms each.

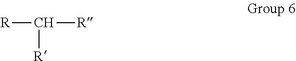

The recovery process of operation 230 may be performed by exposing the device structure 300 to a recovery precursor at operation 232. The recovery process of operation 230 may be performed by placing the device structure 300 into a processing chamber, for example, the processing chamber 100, vaporizing the recovery precursor and flowing the vaporized recovery precursor into the processing chamber. The vinyl silane containing compound may alternatively be vaporized in the processing chamber. The recovery precursor may be introduced into the processing chamber through a showerhead, for example, the gas distribution showerhead 116, positioned at an upper portion of the processing chamber. A carrier gas, such as helium, argon, or combinations thereof may be used to assist the flow of the recovery precursor into the processing chamber.

In some embodiments, operation 230 may be conducted at a processing chamber pressure in a range from about 3 Torr and about 100 Torr, for example, from about 20 Torr to about 50 Torr. The device structure 300 may be heated to a temperature in a range from about 75° C. and about 500° C., for example, from about 200° C. to about 390° C. The flow rate of the recovery precursor may be in a range from about 100 mgm to about 2,000 mgm. The flow rate of the optional carrier gas may be in a range from about 1 sccm to about 10,000 sccm, for example, from about 1,000 sccm to about 5,000 sccm. The processing time may be in a range from about 1 min to about 10 minutes, such as about 3 min. The UV lamp power may be in a range from about 0% to about 90%, for example,

The recovery process of operation 230 may further include exposing the device structure 300 to an ultraviolet (UV) cure process at operation 234 to repair the dielectric layer 304. The UV cure process of operation 234 may be performed prior to the process of operation 232, simultaneously with the process of operation 232, subsequent to the process of operation 232, partially overlapping with the process of operation 232 or any combination of the aforementioned sequences. The UV cure process of operation 232 includes exposing the device structure 300 to UV radiation. The UV cure process of operation 234 may remove Si—H from the dielectric layer 304 and/or water from the damaged pores and facilitate formation of the Si—O—Si(CH₃)₃ groups in the dielectric layer 304, which are shown in FIG. 4C. The UV cure process may be conducted by placing the device structure 300 into a processing chamber, for example, the processing chamber 100 and engaging a source of UV radiation to expose the dielectric layer 304 to the UV radiation. The UV radiation source may be a UV light, for example, the UV light 152. The UV radiation source may be positioned outside of the processing chamber, and the processing chamber may have a quartz window through which UV radiation may pass. The device structure 300 may be positioned in an inert gas environment, such as He or Ar, for example.

Optionally, at operation 240, the device structure 300, may be exposed to a treatment process to remove any additional contaminants and/or residue remaining on the device structure 300 from the prior processing operations. The treatment process of operation 240 can include dry etching, wet cleaning, or combinations thereof. In some embodiments, operation 240 includes exposing the device structure 300 to a hydrofluoric acid (HF) solution. The hydrofluoric acid solution may be in liquid or vapor phase. The hydrofluoric acid solution may be a dilute hydrofluoric (DHF) acid solution. The hydrofluoric acid may be buffered, buffered hydrofluoric acid (BHF), or non-buffered. Exemplary buffering agents for buffering HF include ammonium fluoride (NH₄F). The hydrofluoric acid solution is chosen because it is believed that the hydrofluoric acid solution will remove native oxides from the surface of the device structure 300.

At operation 250 and as illustrated in FIG. 3D, the feature 306 is filled or partially filled with a metal fill material 320 by use of selective deposition process at a first deposition rate. The metal fill material 320 can be formed by a selective bottom-up deposition process. The metal fill material 320 may be formed by any suitable deposition process such as an atomic layer deposition (ALD) process, a chemical vapor deposition (CVD) process, a hybrid ALD/CVD process, a plasma enhanced ALD (PEALD) process, a plasma enhanced CVD (PECVD) process, or the like. In some embodiments, the metal fill material 320 includes molybdenum (Mo). In other embodiments, the metal fill material 320 can be a metal selected from a group comprising, consisting of, or consisting essentially of tungsten (W), cobalt (Co), copper (Cu), ruthenium (Ru), or other useful metals. In one example, precursors used during the deposition process may include molybdenum-containing precursors selected from molybdenum chlorides (e.g., MoClₓ [x=2-6]), molybdenum fluorides (MoF₆)). In some embodiments, the molybdenum chloride can be or include molybdenum (II) chloride, molybdenum (III) chloride, molybdenum (IV) chloride, molybdenum (V) chloride, molybdenum (IV) chloride, or a combination thereof. In particular embodiments, the molybdenum chloride precursor can be or include molybdenum (V) chloride that is molybdenum pentachloride (MoCl₅). Suitable examples of the metal containing precursor include Mo(NMe₂)₄, MoCl₅, MoF₆, molybdenum tetramethylheptane-3,5-dionato (Mo(thd)₃), Mo(CO)₆, and the like that are used to form a molybdenum containing layer.

In one example, the metal fill material 320 deposition process includes a CVD process that includes injecting a molybdenum containing precursor (e.g., molybdenum pentachloride (MoCl₅)), hydrogen (H₂) and a carrier gas (e.g., argon (Ar)) into a processing chamber, while maintaining the device substrate 302 disposed within the processing chamber at a temperature in a range of about 300 to 425° C. In some embodiments, an ampoule temperature of an ampoule that includes the molybdenum containing precursor, which positioned upstream of the processing chamber environment, is maintained at a lower temperature than the temperature within the processing chamber. For example, the ampoule temperature may be maintained in a range of about 60 to 90° C. In certain embodiments, a pressure within the processing chamber during the deposition process may be maintained in a range of about 5 to 50 Torr.

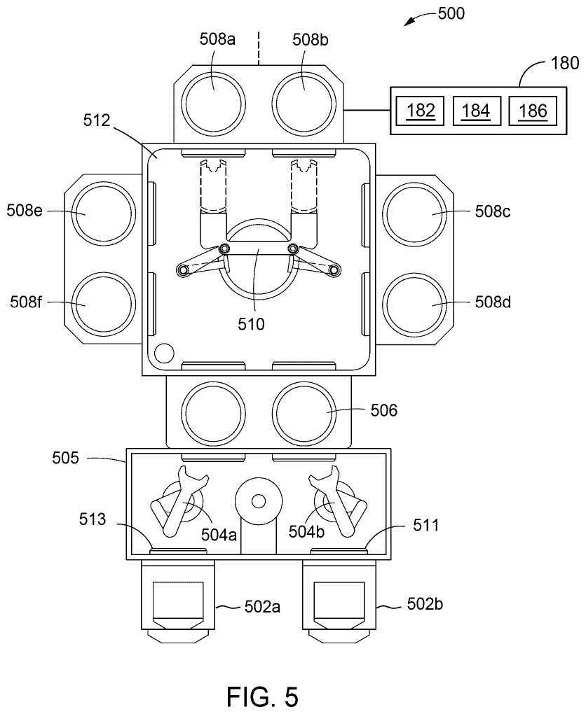

FIG. 5 illustrates a schematic top view of a multi-chamber processing system 500 according to one or more embodiments. The multi-chamber processing system 500 can be used for performing various operations of the method 200. For example, the repair process of operation 230 and filling the feature with metal of operation 250 for an MOL or BEOL electrical connection. As detailed herein, substrates in the multi-chamber processing system 500 can be processed in and transferred between the various chambers without exposing the substrates to an ambient environment exterior to the multi-chamber processing system 500, for example, an atmospheric ambient environment such as may be present in a fab. The substrates can be processed in and transferred between the various chambers maintained at a low pressure, for example, less than or equal to about 300 Torr, or a vacuum environment without breaking the low pressure or vacuum environment among various processes performed on the substrates in the multi-chamber processing system 500. Accordingly, the multi-chamber processing system 500 may provide for an integrated solution for processing of substrates.

Examples of multi-chamber processing systems that may be suitably modified in accordance with the teachings provided herein include the Endura®, Producer® or Centura® integrated multi-chamber processing systems or other suitable multi-chamber processing systems commercially available from Applied Materials, Inc., located in Santa Clara, California. It is contemplated that other multi-chamber processing systems (including those from other manufacturers) may be adapted to benefit from aspects described herein.

The multi-chamber processing system 500 generally includes a factory interface 505, a transfer chamber 512, a plurality of twin processing chambers 508a-508b, 508c-508d, and 508e-508f, and the system controller 180 The factory interface 505 typically operates at atmospheric pressure for storing and holding substrates. The factory interface 505 includes at least one atmospheric robot 504a-b, such as a dual-blade atmospheric robot, and is adapted to receive one or more cassettes of substrates.

On a first side of the factory interface 505, one or more load ports 511, 513 may be provided. The load port 511, 513 is adapted to receive from a front opening unified pod (“FOUP”) 502a-b a substrate (e.g., 300 mm diameter wafers) which is to be processed. The FOUP(s) 502a-b has one or more substrate carriers configured to store the substrates temporarily and portably. A load lock chamber 506 is coupled to a second side (opposing to the first side) of the factory interface 505. The load lock chamber 506 is coupled to the transfer chamber 512 to which the plurality of twin processing chambers 508a-508b, 508c-508d and 508e-508f are coupled.

The substrate is transferred by the atmospheric robot 504a-b from the FOUP(s) 502a-b to the load lock chamber 506. A second robotic arm 510 is disposed in the transfer chamber 512 coupled to the load lock chamber 506 to transport the substrates from the load lock chamber 506 to processing chambers 508a-f coupled to the transfer chamber 512. The factory interface 505 therefore provides a transition between the atmospheric environment of the factory interface 505 and the vacuum environment of the tool or processing chambers.

The processing chambers 508a-f may be any type of processing chambers, for example, chemical vapor deposition (CVD) chambers, atomic layer deposition (ALD) chambers, physical vapor deposition (PVD) chambers, ion metal implant (IMP) chambers, plasma etching chambers, annealing chambers, other furnace chambers, etc. In one implementation, the processing chambers 508a-f are configured for depositing, annealing, curing and/or etching a film on a substrate. In one configuration, three pairs of the processing chambers (e.g., 508a-508b, 508c-508d and 508e-508f) may be used to process the film on the substrate. In one implementation, at least one of the processing chambers 508a-f is a vapor deposition chamber that includes UV radiation for assisting a silylation reaction, for example, the processing chamber 100 shown in FIG. 1, and another of the process chambers is a vapor deposition chamber for depositing a gap fill metal, for example, molybdenum.

The system controller 180 is coupled to the multi-chamber processing system 500 for controlling the multi-chamber processing system 500 or components thereof. The system controller 180 may be as previously described herein. For example, the system controller 180 may control the operation of the multi-chamber processing system 500 using a direct control of the processing chambers 508a-f of the multi-chamber processing system 500 or by controlling controllers associated with the processing chambers 508a-f. In operation, the system controller 180 enables data collection and feedback from the respective chambers to coordinate performance of the multi-chamber processing system 500.

### Examples

The following non-limiting examples are provided to further illustrate embodiments described herein. However, the examples are not intended to be all inclusive and are not intended to limit the scope of the embodiments described herein.

Table I, reproduced below, demonstrates film surface recovery using the repair processes described herein. The film types labeled “Low K 1” and “Low K 2” are low-k films, for example, silicon oxycarbide (SiOC) films. The molecule used in the repair process is an aminosilane precursor, for example, R2N—Si—(CH3)3 as shown in Group I. Table 1 demonstrates the thickness and water contact angle of “Low K 1” and “Low K 2” prior to exposure of the Low K films to DHF etching (30 second, 100:1), after exposure of the Low K films to DHF etching, after treatment of the Low K films with the aminosilane precursor without UV, and after treatment of the Low K films with the aminosilane precursor in the presence of UV. The rows labeled “pristine” shows the thickness and water contact angle for the low K films prior to NH3 damage. The rows labeled “NH3 damage” shows the thickness and water contact angle for the low K films after NH3 damage. The rows labeled “thermal repair” shows the thickness and water contact angle for the low K films after NH3 damage followed by exposure to the aminosilane precursor without UV. The rows labeled “UV repair” shows the thickness and water contact angle for the low K films after NH3 damage followed by exposure to the aminosilane precursor with UV. As depicted in Table I, both the thermal repair and the UV repair processes demonstrated an improved reduction in change in thickness after DHF etching relative to the films exposed to NH3 damage only.

TABLE I

| | | Thickness/Å | | | Water Contact | |
|---|---|---|---|---|---|---|
| | | | | Δ | Angle/° | |
| Film | | Before | After | (Before − | Before | After |
| Type | Treatment | DHF | DHF | After) | DHF | DHF |
| Low | Pristine Low K 1 | 1010.6 | 1010.2 | 0.4 | 102.8 | 87.8 |
| K 1 | NH3 Damage | 979.3 | 920.9 | 58.4 | 14.8 | 38.3 |
| | Thermal Repair | 974.2 | 925.5 | 48.7 | 89.3 | 37.2 |
| | UV Repair | 956.4 | 955.4 | 1.0 | 89.9 | 81.7 |
| Low | Pristine Low K 2 | 991.2 | 990.9 | 0.3 | 99.4 | 86.5 |
| K 2 | NH3 Damage | 969.5 | 935.0 | 34.5 | 6.0 | 17.8 |
| | Thermal Repair | 975.2 | 941.3 | 33.9 | 83.7 | 19.2 |
| | UV Repair | 974.4 | 973.8 | 0.6 | 93.4 | 83.0 |

The previously described implementations of the present disclosure have many advantages. However, the present disclosure does not necessitate that all the advantageous features and all the advantages need to be incorporated into every implementation of the present disclosure. A surface recovery process that restores the hydrophobicity of dielectric surfaces and promotes selective deposition of metal-fill such as molybdenum onto metal-containing surfaces while reducing or preventing growth on the dielectric surfaces. Additionally, the surface recovery process reduces film loss against subsequent wet etching processes such as DHF. Restoration of hydrophobicity of dielectric sidewalls through the method described herein inhibits metal growth along the sidewalls. As a result, metal-fill deposits mainly on the bottom metal gate and not on the sidewalls. This eliminates the need for the conventional wet clean process performed during current metal-fill processes.

In the Summary and in the Detailed Description, and the Claims, and in the accompanying drawings, reference is made to particular features (including method operations) of the present disclosure. It is to be understood that the disclosure in this specification includes all possible combinations of such particular features. For example, where a particular feature is disclosed in the context of a particular aspect, implementation, embodiment, or example of the present disclosure, or a particular claim, that feature can also be used, to the extent possible in combination with and/or in the context of other particular aspects and implementations of the present disclosure, and in the present disclosure generally.

Embodiments and all the functional operations described in this specification can be implemented in digital electronic circuitry, or in computer software, firmware, or hardware, including the structural means disclosed in this specification and structural equivalents thereof, or in combinations of them. Embodiments described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The term “comprises,” and grammatical equivalents thereof are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

When introducing elements of the present disclosure or exemplary aspects or embodiment(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to embodiments of the present disclosure, other and further embodiments of the disclosure may be devised without departing from the basic scope thereof, and the scope thereof is determined by the claims that follow.

What is claimed is:

1. A method for processing a semiconductor device structure, comprising:
introducing a carbon-containing recovery precursor into a processing region of a processing chamber where the semiconductor device structure is disposed, wherein the semiconductor device structure has:
a feature, the feature having sidewall surfaces defined by a silicon-containing dielectric material and a bottom surface extending between the sidewall surfaces, the bottom surface defined by a metal-containing material; and
exposing the semiconductor device structure to the carbon-containing recovery precursor to increase the hydrophobicity of the sidewall surfaces defined by the silicon-containing dielectric material.

2. The method of claim 1, further comprising:
filling the feature with a metal-fill material, comprising preferentially growing the metal-fill material from the bottom surface defined by the metal-containing material.

3. The method of claim 3, wherein the metal-fill material is molybdenum, and the metal-containing material is tungsten.

4. The method of claim 1, further comprising exposing the semiconductor device substrate to UV light during at least a portion of a time when the carbon-containing recovery precursor is in the processing region.

5. The method of claim 1, further comprising exposing the semiconductor device structure to UV light prior to introducing the carbon-containing recovery precursor into the processing region.

6. The method of claim 1, further comprising exposing the semiconductor device structure to UV light after removing the carbon-containing recovery precursor from the processing region.

7. The method of claim 1, wherein the recovery precursor comprises a molecule selected from a group consisting of: 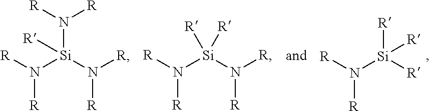
wherein R is independently selected from Me, Et, iPr, tBu, and H, or R and R are joined to form a cyclic chain on one or more N atoms, and R′ is an alkyl, alkenyl, or an alkynyl.

8. The method of claim 1, wherein the recovery precursor comprises a molecule selected from a group consisting of 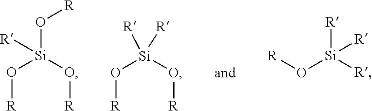
wherein R is independently selected from Me, Et, iPr, and tBu, and R′ is an alkyl, alkenyl, or an alkynyl.

9. The method of claim 1, wherein the recovery precursor comprises a molecule selected from a group consisting of 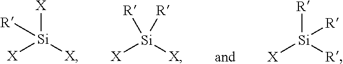
wherein X is Cl, Br, or I, and R′ is an alkyl, alkenyl, or an alkynyl.

10. The method of claim 1, wherein the recovery precursor comprises a molecule with a formula: 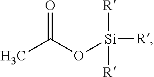
wherein R′ is an alkyl, alkenyl, or an alkynyl.

11. The method of claim 1, wherein the recovery precursor comprises a molecule with a formula: 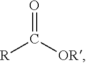
wherein R is hydrogen, an alkyl, an alkenyl, an alkynyl, or an aryl, and R′ is hydrogen, an alkyl, an alkenyl, an alkynyl, or an aryl.

12. The method of claim 1, wherein the recovery precursor comprises a molecule with a formula: 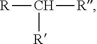
wherein R is hydrogen, an alkyl, an alkenyl, an alkynyl, or an aryl, R′ is hydrogen, an alkyl, an alkenyl, an alkynyl, or an aryl, and R″ is hydrogen, an alkyl, an alkenyl, an alkynyl, or an aryl.

13. A non-transitory computer-readable medium storing instructions that, when executed by a processor, cause a computer system to perform the operations of:
introducing a carbon-containing recovery precursor into a processing region of a processing chamber where the semiconductor device structure is disposed, wherein the semiconductor device structure has:
a feature formed thereon, the feature having sidewall surfaces defined by a silicon-containing dielectric material and a bottom surface extending between the sidewall surfaces, the bottom surface defined by a metal-containing material; and
exposing the semiconductor device structure to the carbon-containing recovery precursor to increase the hydrophobicity of the sidewall surfaces defined by the silicon-containing dielectric material.

14. The non-transitory computer-readable medium of claim 13, further comprising:
filling the feature with a metal-fill material, comprising preferentially growing the metal-fill material from the bottom surface defined by the metal-containing material.

15. The non-transitory computer-readable medium of claim 13, further comprising:
turning on a UV light source to expose the semiconductor device structure to UV light.

16. The non-transitory computer-readable medium of claim 13, further comprising:
adjusting a flow rate of the carbon-containing recovery precursor to be in a range from about 100 mgm to about 2000 mgm.

17. The non-transitory computer-readable medium of claim 16, further comprising:
adjusting a pressure inside the process chamber to be in a range from about 3 Torr and about 100 Torr; and
adjusting a temperature inside the process chamber to be in a range from about 75° C. to about 500° C.

18. A process chamber, comprising:
a chamber body;
a UV transparent gas distribution showerhead, the chamber body and the UV transparent gas distribution showerhead defining a processing volume;
a UV light source positioned to deliver UV radiation into the processing volume;
a process gas source adapted to deliver a processing gas comprising a carbon-containing recovery precursor to the inner volume; and
a system controller, comprising:
a memory storing computer readable instructions; and
a processor coupled to the memory, the processor configured by the computer readable instructions that when executed by the processor perform a plurality of operations for processing a semiconductor device structure, the plurality of operations comprising:
introducing the carbon-containing recovery precursor into the processing volume where the semiconductor device structure is disposed, wherein the semiconductor device structure has:
a feature, the feature having sidewall surfaces defined by a silicon-containing dielectric material and a bottom surface extending between the sidewall surfaces, the bottom surface defined by a metal-containing material; and
exposing the semiconductor device structure to the carbon-containing recovery precursor to increase the hydrophobicity of the sidewall surfaces defined by the silicon-containing dielectric material.

19. The process chamber of claim 18, wherein the plurality of operations further comprises:
turning on the UV light source to expose the semiconductor device structure to UV light.

20. The process chamber of claim 18, wherein the plurality of operations further comprises:
adjusting a flow rate of the carbon-containing recovery precursor to be in a range from about 100 mgm to about 2000 mgm;
adjusting a pressure inside the process chamber to be in a range from about 3 Torr and about 100 Torr; and
adjusting a temperature inside the process chamber to be in a range from about 75° C. to about 500° C.
